(19) United States
(12) Patent Application Publication
(10) Pub. No.: US 2026/0253331 A1
(43) Pub. Date: Aug. 27, 2026

(54) COMPUTER-IMPLEMENTED TECHNOLOGIES FOR CONSTRUCTING A SLIVER-FREE MESH

(71) Applicant: National Technology & Engineering Solutions of Sandia, LLC, Albuquerque, NM (US)

(72) Inventor: Mohamed Salah Ebeida, Parker, TX (US)

(21) Appl. No.: 19/060,129

(22) Filed: Feb. 21, 2025

(51) Int. Cl. G06T 17/20

(52) U.S. Cl. CPC G06T 17/20

(57) ABSTRACT

Various technologies pertaining to constructing a mesh from a computer-implemented model are described. The constructed mesh is free of slivers, which are mesh elements having connecting facets that are nearly flat with respect to one another. Sphere packing and a resampling procedure are undertaken to eliminate slivers in a mesh.

### STATEMENT OF GOVERNMENTAL INTEREST

This invention was made with Government support under Contract No. DE-NA0003525 awarded by the United States Department of Energy/National Nuclear Security Administration. The U.S. Government has certain rights in the invention.

### BACKGROUND

Numerical simulation, which is also referred to as engineering simulation or virtual prototyping, is the process of creating virtual models of products or systems and evaluating the performance of the modeled products or systems under various conditions and scenarios using specialized computer-executable simulation software. The goal of numerical simulation is to improve or optimize a design of the product or system before it is physically manufactured by identifying potential design flaws and areas for improvement; numerical simulation assists manufacturers with determining whether a modeled product or system meets particular design parameters and characteristics, such as strength, safety, deterioration, expected lifespan, etc. In addition, numerical simulation can be used in connection with verifying and validating manufacturability of a product or system.

In connection with performing numerical simulation, computer-aided drafting (CAD) software is employed by a designer to create a CAD model that is to be subject to testing; thereafter, a three-dimensional mesh of the CAD model is generated, and the mesh is provided as input to the specialized computer-executable simulation software. The generation of high-quality, three-dimensional meshes is an active field of research, where a tetrahedral mesh is one meshing framework. Delaunay-based algorithms for generating tetrahedral meshes based upon an input CAD model provide certain quality guarantees about a constructed mesh, where such guarantees rule out most problematic elements (where problematic elements are parts of a constructed mesh that may cause the simulation software to crash or consume an inordinate amount of computing resourced when performing a simulation). The guarantees, however, do not apply to slivers, which are elements of a tetrahedral mesh that are essentially flat (e.g., where dihedral angles between facets are 20 degrees or less or 160 degrees or more) and can render meshes useless for the purposes of simulation and analysis. In practice, simulation software is configured to reject meshes that include even a small number of sliver elements. While efforts have been made to address slivers in meshes, there are currently no suitable technologies that are capable of outputting tetrahedral meshes that are guaranteed to be free of slivers.

### SUMMARY

The following is a brief summary of subject matter that is described in greater detail herein. This summary is not intended to be limiting as to the scope of the claims.

Described herein are various technologies related to constructing meshes from computer-aided drafting (CAD) models, where the meshes are guaranteed to be free of slivers. Numerical simulation can thereafter be performed with respect to such meshes. In connection with constructing a mesh, a computing system executes a sphere-based, tetrahedral meshing algorithm that employs maximal Poisson-disk sampling (MPS) to establish quality guarantees, where such guarantees include quality guarantees on edge-length ratios and angles of triangular facets. In addition, the computing system performs a resampling procedure that is designed to eliminate problematic sliver elements (slivers). A sliver is a near-flat element that is characterized by dihedral angles between facets of less than 20° or above 160°. In addition, with regard to mesh sizing, the computing system decouples estimation of the sizing function from the core meshing phase so that radii of spheres do not change during meshing. Further, the computing system extends the sizing function to the interior of the domain before meshing, where the sizing function is guaranteed to satisfy a Lipshitz sizing constraint.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

FIG. 1 is a functional block diagram of a computing system that is configured to generate a mesh of an object, where the mesh is free of slivers.

FIG. 2 is a flow diagram illustrating a method for forming a point cloud representation of a surface of an object.

FIG. 3 depicts a surface mesh of an object.

FIG. 4 depicts a point cloud representation of the object.

FIG. 5 is a flow diagram illustrating a method for computing a sizing function that is used to generate a mesh of an object.

FIG. 6 is a schematic that illustrates that a sizing function that is Lipshitz-continuous on a surface of an object does not guarantee Lipschitz-continuity in the interior of the object.

FIG. 7 graphically depicts a sizing function for an object.

FIG. 8 is a flow diagram illustrating a method for generating a surface mesh that is free of slivers.

FIG. 9 graphically depicts sphere packing performed on a surface of an object.

FIG. 10 is a flow diagram illustrating a method for extending a surface mesh through an interior of an object, where the completed mesh is free of slivers.

FIGS. 11A-11D are schematics that depict aspects pertaining to generating a mesh for an object, where the generated mesh is free of slivers.

FIGS. 12A-12B are two-dimensional renderings that depict protection of surface triangulation as a mesh is extended to an interior of an object.

FIG. 13 is a cutaway view of an object that depicts an interior mesh that is free of slivers.

FIG. 14 is a schematic of a computing system.

### DETAILED DESCRIPTION

Various technologies pertaining to construction of sliver-free tetrahedral meshes are now described with reference to the drawings, where like reference numerals are used to refer to like elements throughout. In the following description, for purposes of explanation, numerous specific details are set forth in order to provide a thorough understanding of one or more aspects. It may be evident, however, that such aspect(s) may be practiced without these specific details. In other instances, well-known structures and devices are shown in block diagram form in order to facilitate describing one or more aspects. Further, it is to be understood that functionality that is described as being carried out by certain system components may be performed by multiple components. Similarly, for instance, a component may be configured to perform functionality that is described as being carried out by multiple components.

Additionally, the term “or” is intended to mean an inclusive “or” rather than an exclusive “or.” That is, unless specified otherwise, or clear from the context, the phrase “X employs A or B” is intended to mean any of the natural inclusive permutations. Hence, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Further, as used herein, the terms “component,” “module,” and “system” are intended to encompass computer-readable data storage that is configured with computer-executable instructions that cause certain functionality to be performed when executed by a processor. The computer-executable instructions may include a routine, a function, or the like. It is also to be understood that a component, module, or system may be localized on a single device or distributed across several devices.

Described herein are computer-implemented technologies for generating a tetrahedral mesh that is guaranteed to be free of slivers, where the mesh is based upon a three-dimensional computer-aided drafting (CAD) model. Meshing algorithms are used in the analysis of physical systems; however, existing technologies for generating three-dimensional meshes often produce meshes with elements, such as slivers, that can lead to unreliable results and/or significant use of computational resources when the mesh is analyzed using numerical simulation systems. The technologies described herein improve upon existing technologies for generating three-dimensional meshes, as the technologies described herein are configured to generate sliver-free tetrahedral meshes. With more specificity, described herein are computer-implemented technologies that employ maximal Poisson-disk sampling (MPS) to establish quality guarantees including bounds on edge-length ratios and angles of triangular facets. A local vertex-resampling procedure is employed to eliminate slivers; for example, empirically it has been observed that meshes can be produced with minimum dihedral angles of 30°, which is a substantiable improvement over conventional state-of-the art technologies.

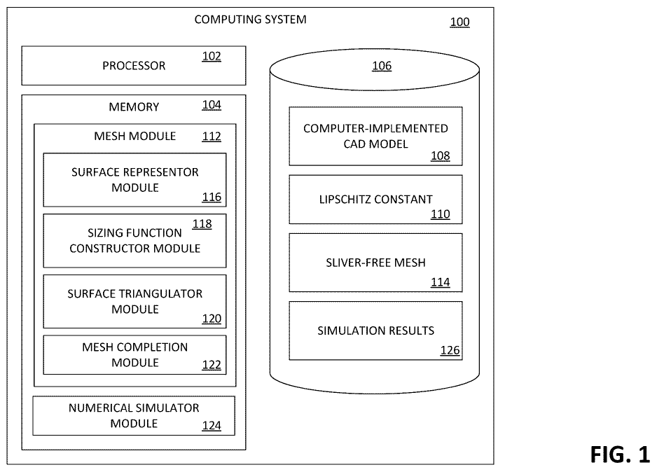

With reference now to FIG. 1, a computing system 100 is illustrated, where the computing system 100 is configured to generate tetrahedral meshes that are free of slivers, and further where such meshes are based upon three-dimensional CAD models of objects (products, systems, etc.). The computing system 100 includes a processor 102, memory 104, and a data store 106, where the data store 106 includes data that is accessible to the processor 102. The memory 104 includes instructions that are executed by the processor 102 as well as data that is accessible to the processor 102. The data store 106 includes a computer-implemented CAD model 108, where such model 108 can be a model of an object that is to be subject to analysis by way of numerical simulation. The data store 106 additionally includes a value (L) for a Lipschitz constant 110. The Lipschitz constant 110 can be defined by an analyst.

The memory 104 includes a mesh module 112 that, when executed by the processor 102, receives the model 108 and the constant 110 as input, and outputs a sliver-free mesh 114, where the sliver-free mesh 114 is stored in the data store 106. The mesh module 112 includes several modules that perform various operations in connection with generating the mesh 114; these modules comprise a surface representor module 116, a sizing function constructor module 118, a surface triangulator module 120, and a mesh completion module 122. Operations performed by such modules are described in greater detail below. The memory 104 also includes a numerical simulator module 124, where the numerical simulator module 124, when executed by the processor 102, receives the sliver-free mesh 114 and outputs simulation results 126. The simulation results 126 can indicate information such as tensile strength of the object modeled by the model 108, aerodynamic information associated with the object modeled by the model 108, etc.

Briefly, the mesh module 112 receives the model 108 as input, where the model 108 includes a surface triangulation [symbol] ᵢₙₚᵤₜ for the boundary [symbol] =∂Ω of the object modeled by the model 108, and further where the boundary is of a bounded, open domain Ω⊂ [symbol] ³. The surface of the object is smooth and the triangulation is watertight and non-self-intersecting. The mesh module 112 is configured to construct a tetrahedral mesh for the domain 22 that: 1) accurately models the geometry of the surface; 2) adheres to a Lipshitz-continuous mesh sizing; 3) has a fixed bound on the ratio of edge lengths; 4) bounds the minimum and maximum angles between edges; and 5) does not include any slivers on the surface or the interior of the mesh.

To generate such a mesh, the modules of the mesh module 112 collectively execute the following algorithm:

### Algorithm 1—Meshing Algorithm

Input: surface triangulation [symbol] ᵢₙₚᵤₜ, Lipschitz constant L
[symbol] ←refine [symbol] ᵢₙₚᵤₜ using adaptive loop subdivision;
[symbol] ←point cloud and normal vectors sampled uniformly from [symbol] ;
ƒ←L-Lipshitz sizing function on bounding box;
[symbol] ←sphere packing on surface with respect to sizing function ƒ;
Resample sphere locations to eliminate slivers on surface;
Protect surface triangulation with interior spheres;
Resample sphere locations to remove slivers;
Return Delaunay Mesh ( [symbol] ∪S_{Ω}).

This algorithm exhibits several improvements over conventional technologies for constructing meshes; for example, the mesh module 112 decouples estimation of the sizing function from the core meshing phase, and therefore radii of spheres do not change during meshing. Further, the sizing function is extended to the interior of the domain before meshing and is guaranteed to satisfy the Lipshitz sizing constraint 110 globally. Moreover, the algorithm includes a resampling procedure that is configured to prevent the output mesh from including problematic slivers. Operation of the individual modules 116-122 of the mesh module 112 are now described in greater detail.

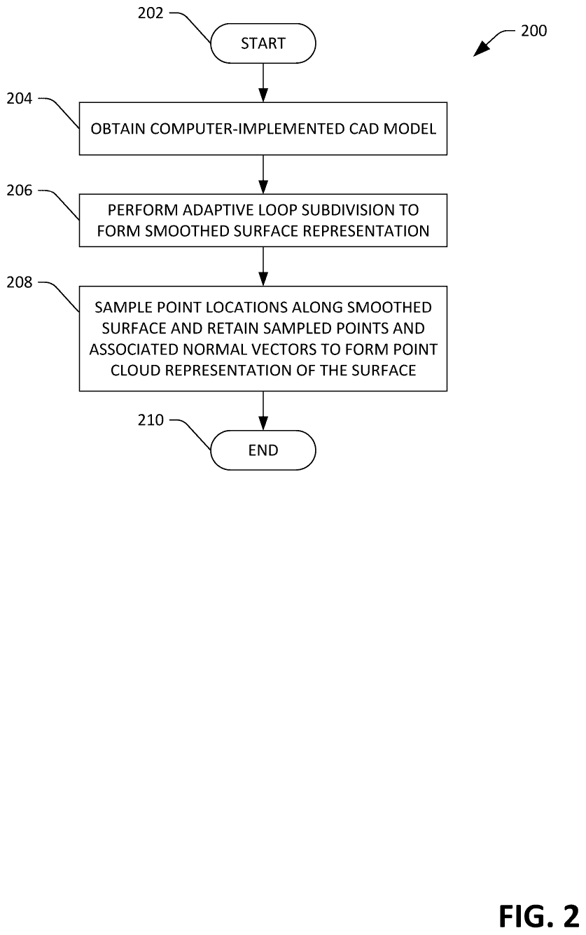

FIGS. 2, 5, 8, and 10 are flow diagrams that represent methods performed by the modules 116-122 of the mesh module 112. While the methods are shown and described as being a series of acts that are performed in a sequence, it is to be understood and appreciated that the methods are not limited by the order of the sequence. For example, some acts can occur in a different order than what is described herein. In addition, an act can occur concurrently with another act. Further, in some instances, not all acts may be required to implement a method described herein.

Moreover, the acts described herein may be computer-executable instructions that can be implemented by one or more processors and/or stored on a computer-readable medium or media. The computer-executable instructions can include a routine, a sub-routine, programs, a thread of execution, and/or the like. Still further, results of acts of the methodologies can be stored in a computer-readable medium, displayed on a display device, transmitted by way of a network connection to a computing system, etc.

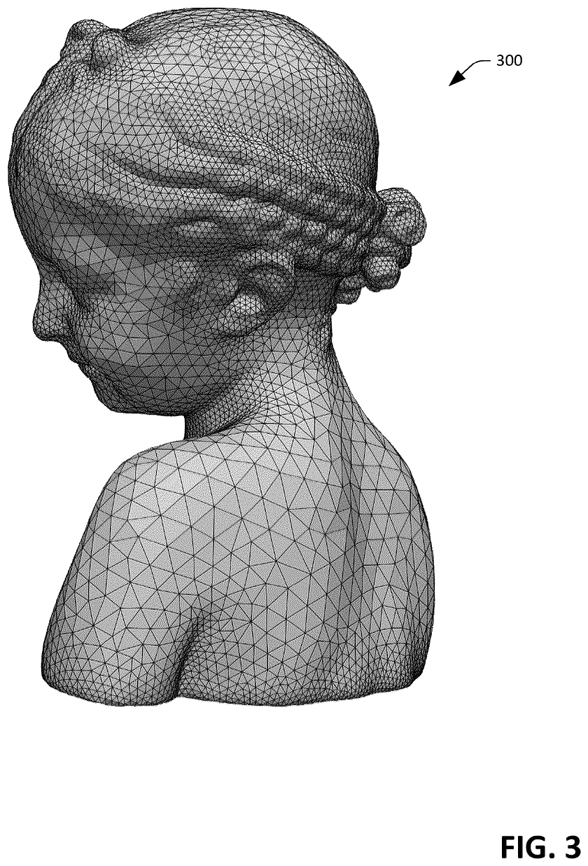

Referring now solely to FIG. 2, a method 200 depicting operations performed by the surface representor module 116 is illustrated. The method 200 starts at 202, and at 204 the computer-implemented CAD model 108 is obtained from the data store 106. The surface triangulation [symbol] ᵢₙₚᵤₜ is obtained from the model 108. Referring briefly to FIG. 3, an example of a surface triangulation 300 is depicted. Returning to FIG. 2, at 206, the surface representor module 116 performs adaptive loop subdivision on [symbol] ᵢₙₚᵤₜ to form a sufficiently smooth representation of the surface geometry [symbol] . Adaptive loop subdivision smooths the input triangulation and ensures that all dihedral angles are greater than a specified tolerance, θₜₒₗ≈175°.

At 208, upon the surface representor module 116 refining the input triangulation [symbol] ᵢₙₚᵤₜ, the surface representor module 116 constructs a point cloud representation of the surface. More specifically, the surface representor module 116 samples (e.g., uniformly samples) point locations on [symbol] and computes a normal vector for each sampled point. The surface representor module 116 causes the sampled points and normal vectors to be stored in the memory 104 and/or the data store 106 as a point cloud representation of the surface of the object. The method 200 completes at 210.

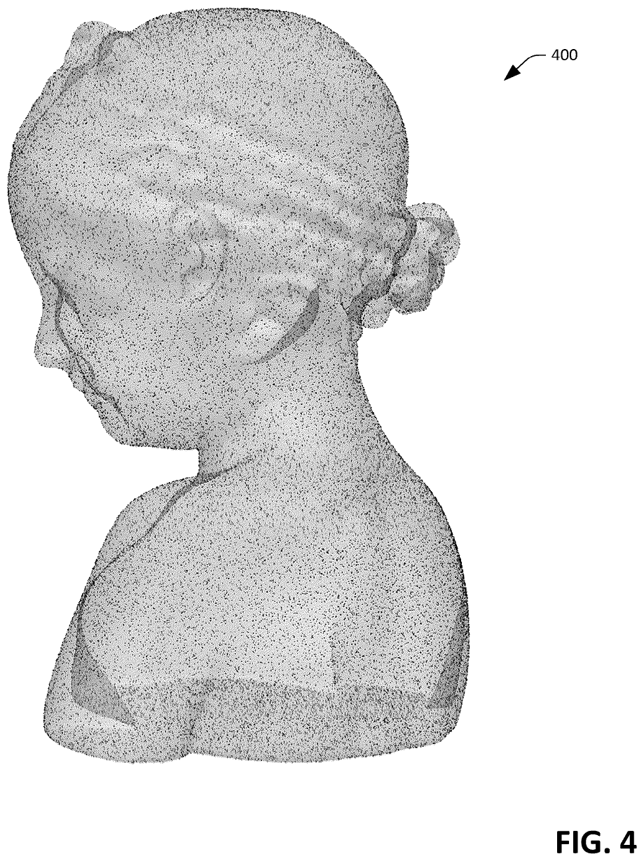

FIG. 4 illustrates an example point cloud representation 400 of the surface of an object as output by the surface representor module 116.

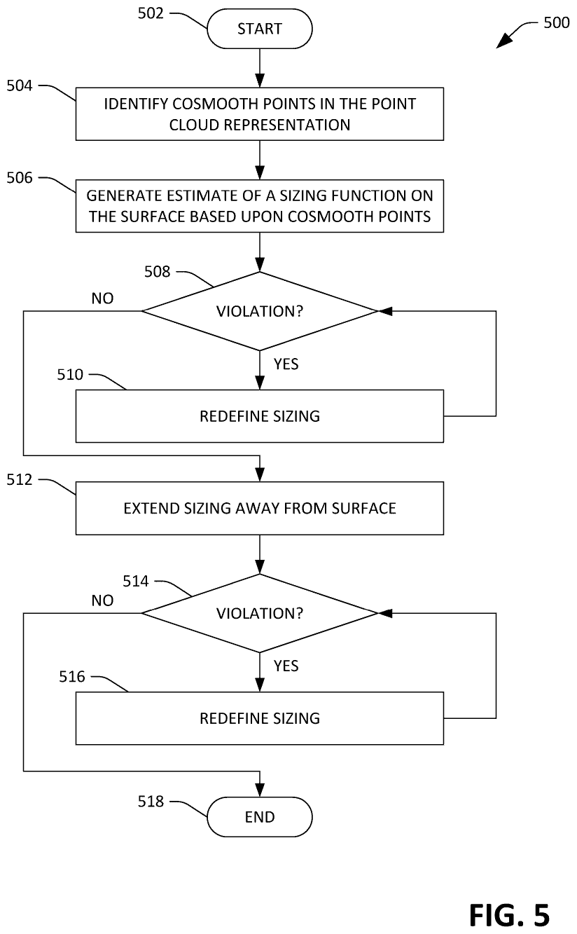

With reference now to FIG. 5, a flow diagram illustrating a method 500 performed by the sizing function constructor module 118 is depicted, where the sizing function constructor module 118 performs the method 500 in connection with constructing a sizing function for the mesh based upon the point cloud representation output by the surface representor module 116. The method 500 starts at 502, and at 504 cosmooth points in the point cloud representation output by the surface representor module 116 are identified. With more particularity, the sizing function constructor module 118 determines an appropriate mesh sizing on the surface of the CAD model 108 using a local notion of smoothness, where two points are identified as being cosmooth when their normal vectors are near parallel to one another and are near-orthogonal to a line segment that connects the two points. In an example, the sizing function constructor module 118 identifies points (a, \vec{n}ₐ) and (b, \vec{n}_{b}) as being cosmooth relative to a user-specified tolerance θₛₘₒₒₜₕ≈20° when:

$$( CS 1 ) ∠ ( {\vec{n}}_{a} , {\vec{n}}_{b} ) is within {θ}_{smooth} of 0 ° or 180 ° ; and$$

$$( CS 2 ) ∠ ( {\vec{n}}_{a} , b - a ) and ∠ ( {\vec{n}}_{b} , a - b ) are both within {θ}_{smooth} of 90 ° .$$

The sizing function constructor module 118 specifies a sizing function that prevents edges from forming between any points that are not identified as being co-smooth. The sizing function constructor module 118 further ensures that the sizing function is Lipshitz continuous throughout the domain, relative to the Lipschitz constant (110) L∈[0,0.5):

$$\vert f ( p ) - f ( {p}^{′} ) \vert \leq L \cdot d ( p , {p}^{′} ) ∀ p , {p}^{′} ∈ ℳ ⋃ Ω . \qquad ( 1 )$$

In connection with constructing the sizing function, at 506, the sizing function constructor module 118 generates an estimate of the sizing function on the surface based on the cosmooth points. To do so, the sizing function constructor module 118 aims to assign each point a sizing that is slightly less than half of the distance to a closest cosmooth point (thereby preventing non-cosmooth points from sharing an edge). The sizing function constructor module 118 estimates the distance by sampling from the point cloud [symbol] , and defines the target sizing for each point p∈ [symbol] by:

$$f ( p ) = 0.49 \cdot min \{ d ( p , {p}^{′} ) : {p}^{′} ∈ 𝒟 non - cosmooth with p \} . \qquad ( 2 )$$

The sizing function constructor module 118 can construct a k-d tree for the point cloud to efficiently compute such sizing, and can apply dart-throwing to sample a set of “sizing spheres,” S_{sizing} that cover the surface:

$$i . e . , 𝒟 ⊂ {⋃}_{s ∈ {S}_{s i z i n g}} B ( s ) with s ∉ B ( {s}^{′} ) ∀ {s}^{′} \neq s \qquad ( 3 )$$

where B(s) denotes the ball centered at s∈S_{sizing} with radius equal to the sizing value ƒ(s). Such spheres provide an estimate of the target sizing function; however, such target may not satisfy the Lipshitz requirement. To account for this, the sizing function constructor module 118 refines the sizing on the surface prior to extending the sizing to the interior.

In more detail, the sizing function constructor module 118, at 508, ensures that the Lipschitz constraint 110 is respected on the surface by making a series of passes over the sizing spheres and determining whether there are any violations of the Lipschitz constraint 110. When it is determined at 508 that the Lipschitz constraint 110 between two points is violated (s, s′∈S_{sizing}, with ƒ(s)>ƒ(s′)), at 510 the sizing function constructor module 118 redefines the sizing by:

$$f ( s ) = f ( {s}^{′} ) + L \cdot d ( s , {s}^{′} ) . \qquad ( 4 )$$

Thus, the sizing function constructor module 118 alters a size of the larger of the two sizing spheres. The sizing function constructor module 118 repeats acts 508 and 510 until a complete pass is made without any violations of the Lipschitz condition being identified, whereupon the method 500 proceeds to 512.

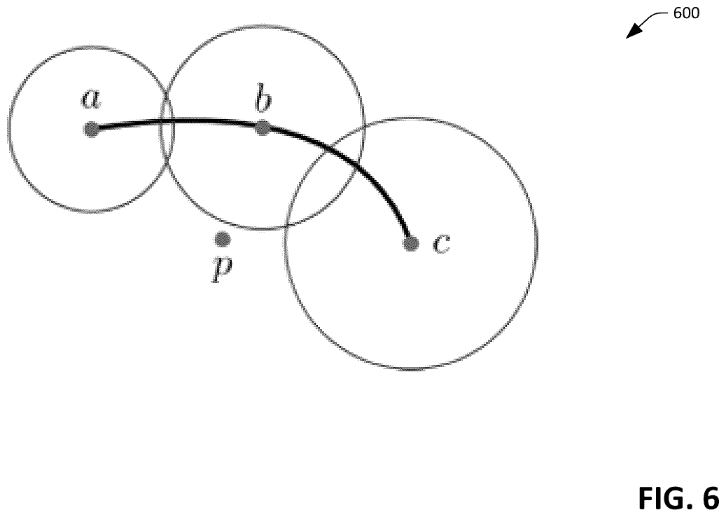

At 512, the sizing function constructor module 118 extends the sizing away from the surface. While the sizing function is now Lipshitz-continuous on the surface, there is no guarantee that it admits a Lipschitz extension away from the surface. Referring briefly to FIG. 6, a schematic 600 is presented, where the schematic 600 illustrates that a sizing function that is Lipshitz-continuous on a surface does not guarantee a Lipschitz extension. The schematic 600 depicts three points a, b, and c on a surface, with corresponding sphere sizes computed for the surface as described above. When, however, ƒ(b)=ƒ(a)+L·d(a, b) and ƒ(c)=ƒ(bL+L·d(b, c), the Lipschitz condition will be violated for any point, p, with d(p, a)≤d(b,a) and d(p,c)<(b,c).

Returning to FIG. 5, in connection with extending the sizing function away from the surface, the sizing function constructor module 118 extends the sizing function to a bounding box of the domain, Ω_{bbox}\ [symbol] by:

$$f ( p ) = f ( s ) + L \cdot d ( p , s ) with s = arg {min}_{s ∈ {S}_{s i z i n g}} d ( p , s ) . \qquad ( 5 )$$

Since larger sizing values results in smaller element counts in the final mesh, the sizing function constructor module 118 assigns points away from the surface the largest possible sizing relative to the Lipschitz constraint. The sizing function constructor module 118 applies dart-throwing to cover the bounding box Ω_{bbox}, with sphere radii determined by the aforementioned optimistic sizing rule. This approach will likely violate the Lipschitz constraint 110; accordingly, the sizing function constructor module 118 employs a similar approach as was used to ensure Lipshitz continuity on the surface.

With more particularity, the sizing function constructor module 118 makes repeated passes through the sizing spheres and, at 514, determines whether there are any violations of the Lipschitz constraint. When a violation is identified at 514, the method proceeds to 516, where sizing is redefined to address such violation. In other words, the sizing function constructor module 118 performs pairwise checks and reduces the sizing of spheres according to eq. (4) when violations are encountered. At this stage, the sizing function constructor module 118 ensures that the full domain is covered by the sizing spheres. As sizing spheres shrink during the smoothing procedure, gaps may form in the sphere cover. To account for gaps, the sizing function constructor module 118 tracks spheres whose sizes have been modified and searches for gaps around perimeters of such spheres using MPS. When the sizing function constructor module 118 identifies a gap, new points are sampled until the gap is covered. Upon the sizing function constructor module 118 completing a pass without detecting any Lipschitz violations or gaps in the sizing sphere function, the sizing function is finalized, and the method 500 completes at 518.

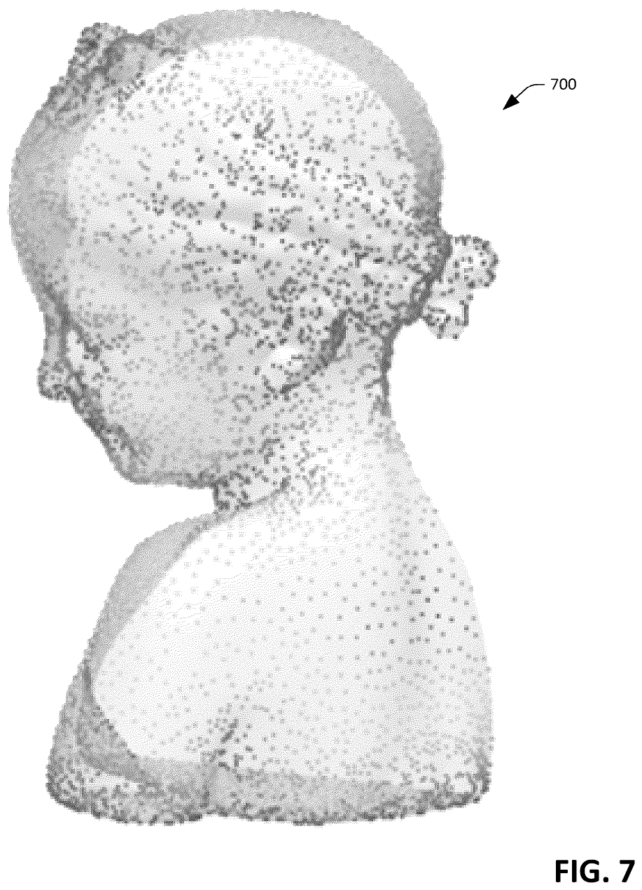

Turning briefly to FIG. 7, a visualization of a sizing function 700 output by the sizing function constructor module 118 is illustrated.

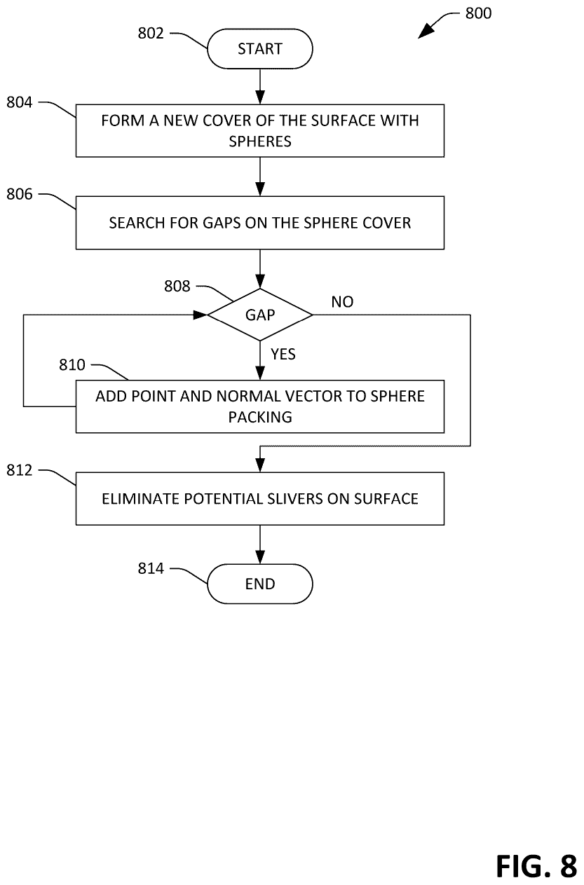

Referring to FIG. 8, a flow diagram illustrating a method 800 performed by the surface triangulator module 120 is depicted, where the surface triangulator module 120 performs the method 800 in connection with constructing a surface triangulation. The method 800 starts at 802, and at 804 a new cover is formed on the surface with spheres. Specifically, the surface triangulator module 120 employs dart-throwing to form a new cover [symbol] of the surface point cloud [symbol] with sphere radii based upon the sizing sphere S_{sizing}. For each sample point p∈ [symbol] , the surface triangulator module 120 computes the sizing using a moving least-squares approximation based on the values at neighboring sizing spheres. While the initial dart-throwing procedure ensures that all sample points from [symbol] are accounted for, it does not guarantee that the full surface [symbol] is covered. Coverage is needed to ensure that the circumradii of Delaunay spheres from the MPS procedure are bounded.

At 806, the surface triangulator module 120 searches for gaps in the current sphere cover by inspecting the perimeter of each sphere. When it is assumed that a sample point has landed on each connected component of the geometry, any gaps that exist on the boundary must border one of the existing spheres. To identify gaps, the surface triangulator module 120 samples from spherical annuli around each sphere. The surface triangulator module 120 iteratively refines grids within the bounding box for each sphere and projects sample points onto the surface to check if the location is already covered.

At 808, a determination is made regarding whether there are any gaps in the sphere cover. When a gap is identified at a location p′, the point and its corresponding normal vector are added to the sphere packing [symbol] at 810. The surface triangulator module 120 can use a quadratic representation Hy of the surface to compute an approximate normal vector for the point p′, and a sizing function can be interpolated using moving least-squares to calculate the radius of the new sphere. The surface triangulator module 120 can repeat this procedure until a full pass over the spheres is completed without encountering any gaps. This ensures that the full surface has been covered and provides bounds on Delaunay circumradii.

At 812, the surface triangulator module 120 eliminates potential slivers on the surface. The surface triangulator module 120 checks for potential slivers using a local procedure at each vertex v∈ [symbol] . The check begins by including temporary points v⁺=v+λ·\vec{n}ᵥ and v⁻=v−λ·\vec{n}ᵥ above and below the point in consideration and collecting all neighboring spheres [symbol] (v). The surface triangulator module forms the Delaunay triangulation associated with {v, v⁺, v⁻}∪ [symbol] (v) and checks each facet to determine whether such facet could potentially form a sliver. If a tetrahedron does not satisfy either of these properties, then a sliver is likely to form on the surface around the point v. In such a problematic case, the surface triangulator module 120 removes v from [symbol] and resamples a new point \tilde{v} within the “unique coverage area” associated with v; that is, the region on ∂Ω which is covered by B(v), but is not covered by any other spheres in the packing.

If a vertex v is resampled, the surface triangulator module 120 marks the new vertex \tilde{v} and its neighbors as “active” so that they will be revised in the next pass through the spheres. The surface triangulator module 120 continues sweeping through the active set until such set is exhausted—this happens when a full pass is made through the sample points and no slivers are encountered. The method 800 completes at 814.

### Theorem 1:

Let τ be a sliver element formed on the surface of a uniform Delaunay triangulation (L=0, R=1). For any vertex v of t, there exists a nearby location \tilde{v}∈ [symbol] such that the circumradius of the tetrahedron formed by replacing v with \tilde{v} has a circumradius greater than one. More precisely, d(v, \tilde{v})≤√2 sin θ, where θ denotes the dihedral angle across the edge opposite of v. If v′ is the vertex of t furthest from v, then there also exists locations \tilde{v}, \tilde{v}∈ [symbol] with

$$d ( v , \tilde{v} ) \leq \sqrt{\frac{2}{3}} tan θ$$

such that the circumradius of the resulting tetrahedron exceeds one.

While the above theorem shows that silvers can be removed from the surface by way of resampling, new slivers that may be formed as a result of this process must be accounted for. The distribution of circumradii associated with potential surface tetrahedra is centered well above the limit Rₘₐₓ=1 (e.g., four neighboring spheres on the surface which may or may not form a tetrahedron in the final mesh). The resampling procedure is capable of producing a change in the circumradius of a given tetrahedron by a magnitude of approximately 0.4 relative to a uniform sphere sizing of one. With the distribution of surface circumradii positioned well above this limit, only a small fraction of these potential tetrahedron have a change of forming a sliver as a result of the resampling procedure.

At this point, a representative set of spheres covering the surface that adhere to a Lipschitz-continuous sizing function established throughout the domain exists. The samples [symbol] induce a two-dimensional triangulation of the surface ∂Ω, and it is desirable to ensure that this surface triangulation remains intact as the mesh is propagated into the interior of the domain. In other words, it is desirable that every triangle from the surface triangulation be included as a facet of a tetrahedron in the final mesh.

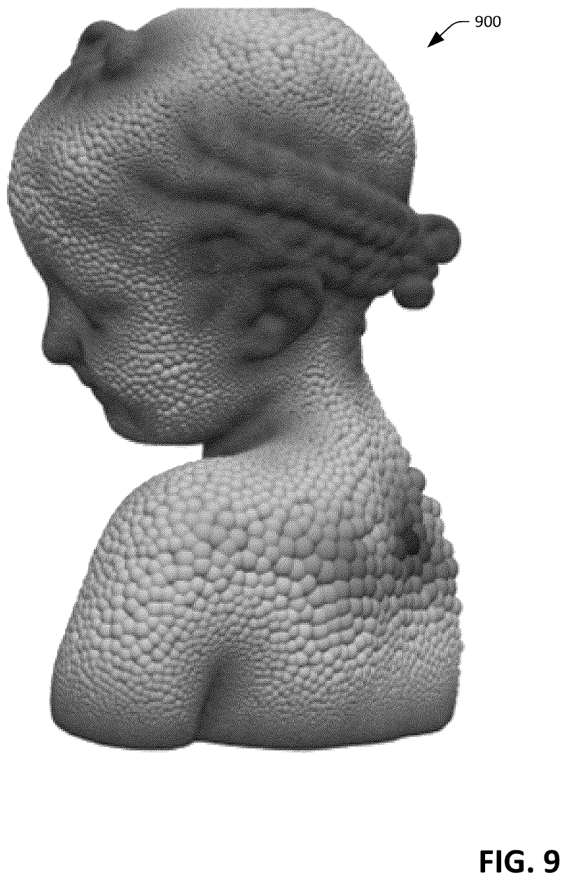

Referring briefly to FIG. 9, a depiction of results of sphere packing performed by the surface triangulator module 120 is shown.

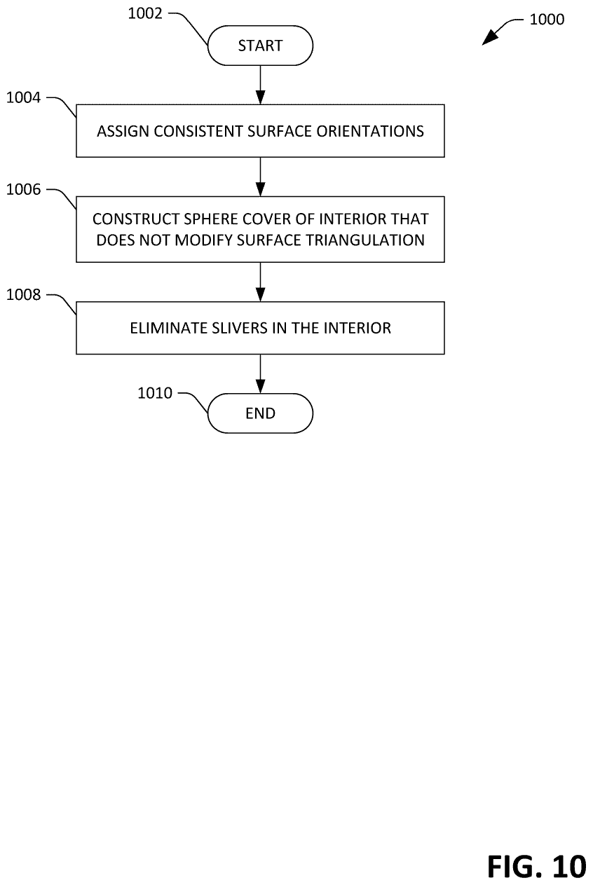

With reference to FIG. 10, a flow diagram illustrating a method 1000 performed by the mesh completion module 122 is presented, where the mesh completion module 122 performs the method 1000 in connection with extending the surface mesh to the interior. The method 1000 starts at 1002, and at 1004 the mesh completion module 122 assigns consistent orientations to the surface. The mesh completion module 122 can identify the appropriate orientation for each component of the surface sequentially; specifically, the mesh completion module 122 selects a corner from the bounding box Ω_{bbox} and retrieves the closest point v∈ [symbol] . The normal \vec{n}ᵥ is oriented based on its position relative to the corner, and such orientation is propagated outward to neighboring spheres on the surface. The outermost component is consistently oriented when this procedure terminates, and the process is repeated until all components have been oriented.

At 1006, the mesh completion module 122 constructs a sphere cover of the interior S_{Ω} that does not modify the triangulation of the surface. This is undertaken as adjustments to the surface triangulation may create slivers that cannot be resolved once the interior spheres are in place. The mesh completion module 122 protects each facet Δ(a, b, c) in the surface triangulation by placing a temporary sphere at the midpoint w_{Δ} of the facet's Voronoi edge E_{Δ}. The facet is included in the final tetrahedral mesh if at least one point on the edge E_{Δ} remains uncovered by all interior spheres. The temporary spheres added by the mesh completion module 122 are used to protect the “witness locations” w_{Δ} by applying an MPS around each sphere B(w_{Δ}). The interior spheres sampled by this procedure will leave each witness uncovered (and thus leave the surface triangulation intact). Once MPS is completed around each witness, the mesh completion module 122 applies MPS to the interior of each temporary sphere to identify gaps that may be left behind once the temporary spheres are removed. If a gap is found, the mesh completion module 122 resamples the interior spheres in the region until the gap is covered.

After the initial layer of interior spheres are placed, the mesh completion module 122 continues to sample new sphere locations until the domain is covered by S_{Ω}. The new samples are drawn using MPS applied around the perimeter of the current “active spheres” (i.e., those spheres which are not already surrounded by other spheres in the cover).

At 1008, slivers are eliminated in the interior. Prior to finalizing the mesh, the mesh completion module 122 inspects each element to determine whether any slivers exist. When a sliver is detected, the mesh completion module 122 resamples the vertices until all the sliver is eliminated; this process repeats until there are no slivers. In the uniform (L=0) case, all slivers can be removed by resampling vertices as long as the mesh does not include adjacent slivers.

### Theorem 2:

Let τ be a sliver element in a uniform Delaunay triangulation (L=0, R=1). For any vertex v of τ, there exists a nearby location \tilde{v}∈Ω such that the circumradius of the tetrahedron formed by replacing v with \tilde{v} has a circumradius greater than one. More precisely, d(v, \tilde{v})≤√2 sin θ, where θ denotes the dihedral angle across the edge opposite of v. If v′ is the vertex of τ furthest from v, then there also exists locations \tilde{v}, \tilde{v}′∈Ω with

$$d ( v , \tilde{v} ) \leq \sqrt{\frac{2}{3}} sin θ and d ( v , \tilde{v} ) \leq \sqrt{\frac{2}{3}} tan θ$$

such that the circumradius of the resulting tetrahedron exceeds one.
The method 1000 completes at 1010.

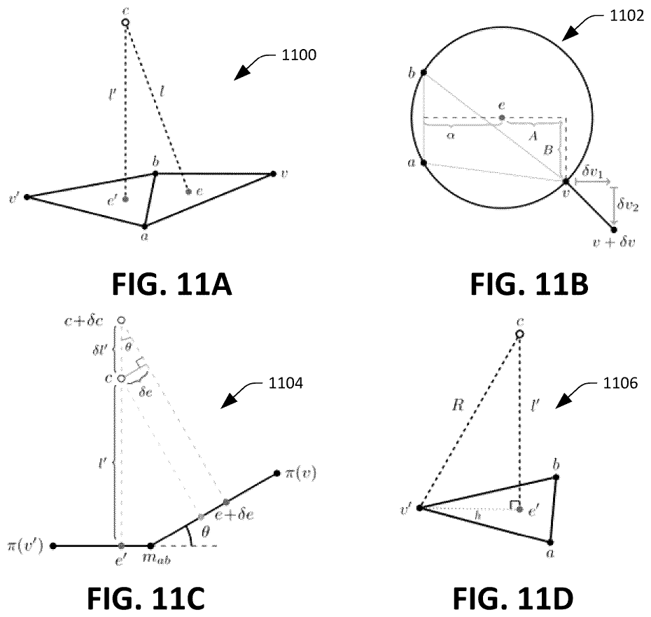

FIGS. 11A-11D are schematics that collectively depict aspects pertaining to sliver elimination performed by the mesh module 112. In FIG. 11A, a schematic 1100 illustrates that a circumcenter of a tetrahedron {a, b, v, v′} lies at the intersection of two Voronoi edges, and such edges are near-parallel when the tetrahedron forms a sliver. FIG. 11B is a schematic 1102 that illustrates that resampling the vertex v induces a change in the triangle's equidistant point; FIG. 11C is a schematic 1104 that illustrates that resampling the vertex v increases the length of the adjacent Voronoi edge. FIG. 11D is a schematic 1106 that depicts elimination of the sliver once R>Rₘₐₓ; this can always be accomplished by resampling in a nearby location.

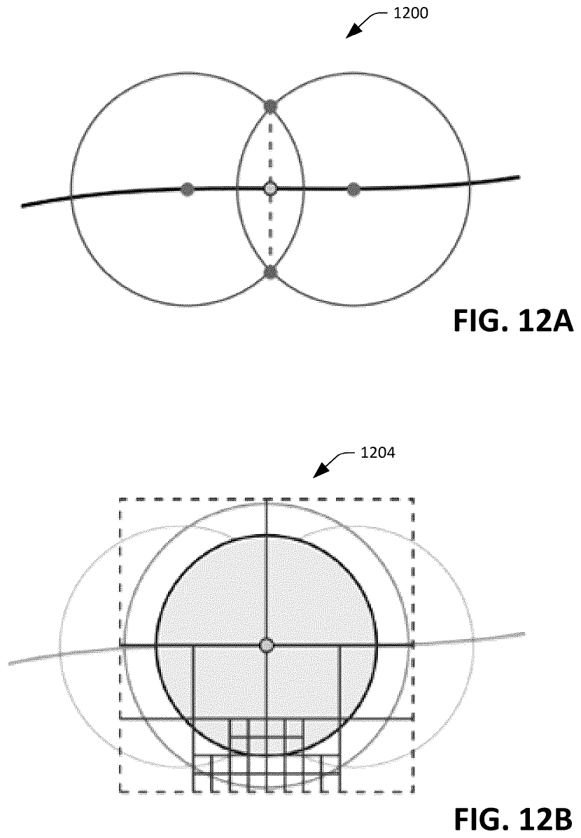

FIGS. 12A and 12B are two-dimensional renderings that depict how surface triangulation is protected before the mesh completion module 122 meshes the interior. FIG. 12A is a schematic 1200 that depicts placement of a witness between the intersection pair associated with each triangle on the surface. FIG. 12B is a schematic 1202 that illustrates addition of temporary spheres around a witness, with a radius determined by the surface sizing and the Lipschitz constant, where MPS is applied to sample the first layer of interior spheres.

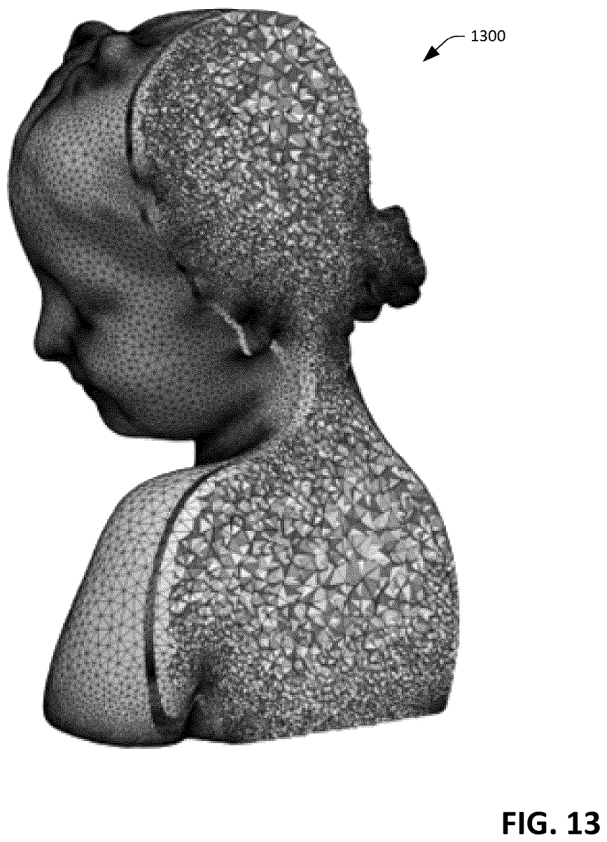

FIG. 13 is a cutaway view of the object 1300 where neither the surface nor the interior mesh includes slivers (where the mesh is output by the mesh completion module 122).

Returning briefly to FIG. 1, the numerical simulator module 124 receives the mesh output by the mesh module 112 and performs a numerical analysis with respect to the mesh. The numerical similar module 124 outputs simulation results 126, which are stored in the data store 106.

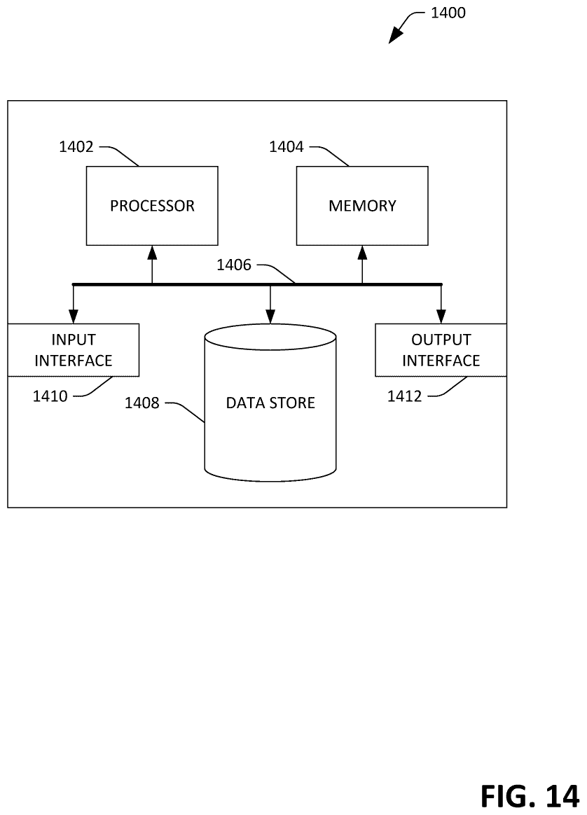

Referring now to FIG. 14, a high-level illustration of an exemplary computing device 1400 that can be used in accordance with the systems and methodologies disclosed herein is illustrated. For instance, the computing device 1400 may be used in a system that constructs meshes based upon computer-implemented models. The computing device 1400 includes at least one processor 1402 that executes instructions that are stored in a memory 1404. The instructions may be, for instance, instructions for implementing functionality described as being carried out by one or more components discussed above or instructions for implementing one or more of the methods described above. The processor 1402 may access the memory 1404 by way of a system bus 1406. In addition to storing executable instructions, the memory 1404 may also store constraints, CAD models, etc.

The computing device 1400 additionally includes a data store 1408 that is accessible by the processor 1402 by way of the system bus 1406. The data store 1408 may include executable instructions, CAD models, partial meshes, etc. The computing device 1400 also includes an input interface 1410 that allows external devices to communicate with the computing device 1400. For instance, the input interface 1410 may be used to receive instructions from an external computer device, from a user, etc. The computing device 1400 also includes an output interface 1412 that interfaces the computing device 1400 with one or more external devices. For example, the computing device 1400 may display text, images, etc. by way of the output interface 1412.

It is contemplated that the external devices that communicate with the computing device 1400 via the input interface 1410 and the output interface 1412 can be included in an environment that provides substantially any type of user interface with which a user can interact. Examples of user interface types include graphical user interfaces, natural user interfaces, and so forth. For instance, a graphical user interface may accept input from a user employing input device(s) such as a keyboard, mouse, remote control, or the like and provide output on an output device such as a display. Further, a natural user interface may enable a user to interact with the computing device 1400 in a manner free from constraints imposed by input device such as keyboards, mice, remote controls, and the like. Rather, a natural user interface can rely on speech recognition, touch and stylus recognition, gesture recognition both on screen and adjacent to the screen, air gestures, head and eye tracking, voice and speech, vision, touch, gestures, machine intelligence, and so forth.

Additionally, while illustrated as a single system, it is to be understood that the computing device 1400 may be a distributed system. Thus, for instance, several devices may be in communication by way of a network connection and may collectively perform tasks described as being performed by the computing device 1400.

Various functions described herein can be implemented in hardware, software, or any combination thereof. If implemented in software, the functions can be stored on or transmitted over as one or more instructions or code on a computer-readable medium. Computer-readable media includes computer-readable storage media. A computer-readable storage media can be any available storage media that can be accessed by a computer. By way of example, and not limitation, such computer-readable storage media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, include compact disc (CD), laser disc, optical disc, digital versatile disc (DVD), floppy disk, and Blu-ray disc (BD), where disks usually reproduce data magnetically and discs usually reproduce data optically with lasers. Further, a propagated signal is not included within the scope of computer-readable storage media. Computer-readable media also includes communication media including any medium that facilitates transfer of a computer program from one place to another. A connection, for instance, can be a communication medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio and microwave are included in the definition of communication medium. Combinations of the above should also be included within the scope of computer-readable media.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

Various technologies have been described herein in accordance with at least the following aspects.

(A1) In an aspect, a method performed by a computing system includes several acts, where the acts include obtaining a surface triangulation for a computer-aided drafting (CAD) model from computer-readable storage. The acts also include constructing a point cloud representation of the surface triangulation, where the point cloud representation is constructed based upon the surface triangulation. The acts further include computing a sizing function for an object modeled by the CAD model, where the sizing function is computed based upon the point cloud representation of the surface triangulation. Computing the sizing function includes: a) covering a surface of the object with first sizing spheres; b) establishing a bounding box that encompasses the object; c) populating the bounding box with second sizing spheres; and d) enforcing Lipshitz continuity with respect to the second spheres. The acts also include constructing a surface mesh based upon the sizing function. The acts additionally include eliminating slivers in the surface mesh. The acts further include extending the surface mesh to an interior of the object to form a final mesh, where the final mesh fails to include any slivers.

(A2) In some embodiments of the method of (A1), the method includes performing numerical simulation based upon the final mesh.

(A3) In some embodiments of the method of at least one of (A1)-(A2), constructing the point cloud representation of the surface triangulation includes: a) performing adaptive loop subdivision to obtain a representation of the geometry of the surface of the object; b) sampling point locations from the representation of the geometry of the surface of the object; and c) for each point, storing a normal vector for the point in the computer-readable data storage, where the point cloud representation comprises the point locations and associated normal vectors.

(A4) In some embodiments of the method of (A3), computing the estimate of the sizing function for the surface of the object includes: a) identifying a violation of a predefined Lipschitz condition between two sizing spheres in the first sizing spheres; and b) altering size of a larger of the two sizing spheres upon identifying the violation.

(A5) In some embodiments of the method of at least one of (A3)-(A4), enforcing Lipshitz continuity with respect to the second sizing spheres to compute the finalized sizing function includes: a) identifying a violation of a predefined Lipschitz condition between two sizing spheres in the second sizing spheres; and b) altering size of a larger of the two sizing spheres upon identifying the violation.

(A6) In some embodiments of the method of (A5), enforcing Lipshitz continuity with respect to the second sizing spheres to compute the finalized sizing function further includes: c) subsequent to altering the size of the larger of the two sizing spheres, identifying that a gap has been created in the bounding box due to the size of the larger of the two sizing spheres being altered; and d) upon identifying that the gap has been created, adding a sphere to the bounding box to cover the gap.

(A7) In some embodiments of the method of (A6), maximal Poisson-disk sampling is employed to identify that the gap has been created.

(A8) In some embodiments of the method of at least one of (A1)-(A7), a sliver is a mesh element having a dihedral angle between facets of greater than 160° or less than 20°.

(B1) In another aspect, a method performed by a computing system includes obtaining a surface triangulation for a computer-aided drafting (CAD) model from computer-readable storage. The method also includes constructing a point cloud representation of the surface triangulation, where the point cloud representation is constructed based upon the surface triangulation. The method additionally includes computing an estimate of a sizing function for a surface of an object modeled by the CAD model, where the estimate of the sizing function is computed based upon the point cloud representation of the surface triangulation, and further where computing the estimate of the sizing function comprises covering the surface with first sizing spheres. The method also includes extending the estimate of the sizing function away from the surface and within a bounding box that encompasses the object, where extending the sizing function comprises populating the bounding box with second sizing spheres. The method additionally includes enforcing Lipshitz continuity with respect to the second sizing spheres to compute a finalized sizing function. The method further includes constructing a surface mesh based upon the sizing function. The method also includes eliminating slivers in the surface mesh. The method additionally includes extending the surface mesh to an interior of the object to form a final mesh, where the final mesh does not include any slivers.

(B2) In some embodiments of the method of (B1), the method also includes performing numerical simulation based upon the final mesh.

(B3) In some embodiments of the method of at least one of (B1)-(B2), constructing the point cloud representation of the surface triangulation includes: a) performing adaptive loop subdivision to obtain a representation of the geometry of the surface of the object; b) sampling point locations from the representation of the geometry of the surface of the object; and c) for each point, storing a normal vector for the point in the computer-readable data storage, where the point cloud representation comprises the point locations and associated normal vectors.

(B4) In some embodiments of the method of (B3), computing the estimate of the sizing function for the surface of the object includes: a) identifying a violation of a predefined Lipschitz condition between two sizing spheres in the first sizing spheres; and b) altering size of a larger of the two sizing spheres upon identifying the violation.

(B5) In some embodiments of the method of at least one of (B3)-(B4), enforcing Lipshitz continuity with respect to the second sizing spheres to compute the finalized sizing function includes: a) identifying a violation of a predefined Lipschitz condition between two sizing spheres in the second sizing spheres; and b) altering size of a larger of the two sizing spheres upon identifying the violation.

(B6) In some embodiments of the method of (B5), enforcing Lipshitz continuity with respect to the second sizing spheres to compute the finalized sizing function further includes: c) subsequent to altering the size of the larger of the two sizing spheres, identifying that a gap has been created in the bounding box due to the size of the larger of the two sizing spheres being altered; and d) upon identifying that the gap has been created, adding a sphere to the bounding box to cover the gap.

(B7) In some embodiments of the method of (B6), maximal Poisson-disk sampling is employed to identify that the gap has been created.

(B8) In some embodiments of the method of at least one of (B1)-(B7), a sliver is a mesh element having a dihedral angle between facets of greater than 160° or less than 20°.

(C1) In another aspect, a computing system includes a processor and memory, where the memory stores instructions that, when executed by the processor, cause the processor to perform at least one of the methods disclosed herein (e.g., any of (A1)-(A8) and (B1)-(B8)).

(D1) In yet another aspect, a computer-readable storage medium includes instructions that, when executed by a processor, cause the processor to perform at least one of the methods disclosed herein (e.g., any of (A1)-(A8) and (B1)-(B8)).

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A computing system, comprising:
a processor; and
memory storing instructions that, when executed by the processor, cause the processor to perform acts comprising:
obtaining a surface triangulation for a computer-aided drafting (CAD) model from computer-readable storage;
constructing a point cloud representation of the surface triangulation, where the point cloud representation is constructed based upon the surface triangulation;
computing an estimate of a sizing function for a surface of an object modeled by the CAD model, where the estimate of the sizing function is computed based upon the point cloud representation of the surface triangulation, and further where computing the estimate of the sizing function comprises covering the surface with first sizing spheres;
extending the estimate of the sizing function away from the surface and within a bounding box that encompasses the object, where extending the sizing function comprises populating the bounding box with second sizing spheres;
enforcing Lipshitz continuity with respect to the second sizing spheres to compute a finalized sizing function;
constructing a surface mesh based upon the sizing function;
eliminating slivers in the surface mesh; and
extending the surface mesh to an interior of the object to form a final mesh, where the final mesh does not include any slivers.

2. The computing system of claim 1, the acts further comprising:
performing numerical simulation based upon the final mesh.

3. The computing system of claim 1, where constructing the point cloud representation of the surface triangulation comprises:
performing adaptive loop subdivision to obtain a representation of the geometry of the surface of the object;
sampling point locations from the representation of the geometry of the surface of the object; and
for each point, storing a normal vector for the point in the computer-readable data storage, where the point cloud representation comprises the point locations and associated normal vectors.

4. The computing system of claim 3, where computing the estimate of the sizing function for the surface of the object comprises:
identifying a violation of a predefined Lipschitz condition between two sizing spheres in the first sizing spheres; and
altering size of a larger of the two sizing spheres upon identifying the violation.

5. The computing system of claim 3, where enforcing Lipshitz continuity with respect to the second sizing spheres to compute the finalized sizing function comprises:
identifying a violation of a predefined Lipschitz condition between two sizing spheres in the second sizing spheres; and
altering size of a larger of the two sizing spheres upon identifying the violation.

6. The computing system of claim 5, where enforcing Lipshitz continuity with respect to the second sizing spheres to compute the finalized sizing function further comprises:
subsequent to altering the size of the larger of the two sizing spheres, identifying that a gap has been created in the bounding box due to the size of the larger of the two sizing spheres being altered; and
upon identifying that the gap has been created, adding a sphere to the bounding box to cover the gap.

7. The computing system of claim 6, where maximal Poisson-disk sampling is employed to identify that the gap has been created.

8. The computing system of claim 1, where a sliver is a mesh element having a dihedral angle between facets of greater than 160° or less than 20°.

9. A method performed by a computing system, the method comprising:
obtaining a surface triangulation for a computer-aided drafting (CAD) model from computer-readable storage;
constructing a point cloud representation of the surface triangulation, where the point cloud representation is constructed based upon the surface triangulation;
computing a sizing function for an object modeled by the CAD model, where the sizing function is computed based upon the point cloud representation of the surface triangulation, and further where computing the sizing function comprises:
covering a surface of the object with first sizing spheres;
establishing a bounding box that encompasses the object;
populating the bounding box with second sizing spheres; and
enforcing Lipshitz continuity with respect to the second spheres;
constructing a surface mesh based upon the sizing function;
eliminating slivers in the surface mesh; and
extending the surface mesh to an interior of the object to form a final mesh, where the final mesh fails to include any slivers.

10. The method of claim 9, further comprising:
performing numerical simulation based upon the final mesh.

11. The method of claim 9, where constructing the point cloud representation of the surface triangulation comprises:
performing adaptive loop subdivision to obtain a representation of the geometry of the surface of the object;
sampling point locations from the representation of the geometry of the surface of the object;
for each point, storing a normal vector for the point in the computer-readable data storage, where the point cloud representation comprises the point locations and associated normal vectors.

12. The method of claim 11, where computing the estimate of the sizing function for the surface of the object comprises:
identifying a violation of a predefined Lipschitz condition between two sizing spheres in the first sizing spheres; and
altering size of a larger of the two sizing spheres upon identifying the violation.

13. The method of claim 11, where enforcing Lipshitz continuity with respect to the second sizing spheres to compute the finalized sizing function comprises:
identifying a violation of a predefined Lipschitz condition between two sizing spheres in the second sizing spheres; and
altering size of a larger of the two sizing spheres upon identifying the violation.

14. The method of claim 13, where enforcing Lipshitz continuity with respect to the second sizing spheres to compute the finalized sizing function further comprises:
subsequent to altering the size of the larger of the two sizing spheres, identifying that a gap has been created in the bounding box due to the size of the larger of the two sizing spheres being altered; and
upon identifying that the gap has been created, adding a sphere to the bounding box to cover the gap.

15. The method of claim 14, where maximal Poisson-disk sampling is employed to identify that the gap has been created.

16. The method of claim 9, where a sliver is a mesh element having a dihedral angle between facets of greater than 160° or less than 20°.

17. A computer-readable storage medium comprising instructions that, when executed by a processor, cause the processor to perform acts comprising:
obtaining a surface triangulation for a computer-aided drafting (CAD) model from computer-readable storage;
constructing a point cloud representation of the surface triangulation, where the point cloud representation is constructed based upon the surface triangulation;
computing an estimate of a sizing function for a surface of an object modeled by the CAD model, where the estimate of the sizing function is computed based upon the point cloud representation of the surface triangulation, and further where computing the estimate of the sizing function comprises covering the surface with first sizing spheres;
extending the estimate of the sizing function away from the surface and within a bounding box that encompasses the object, where extending the sizing function comprises populating the bounding box with second sizing spheres;
enforcing Lipshitz continuity with respect to the second sizing spheres to compute a finalized sizing function;
constructing a surface mesh based upon the sizing function;
eliminating slivers in the surface mesh; and
extending the surface mesh to an interior of the object to form a final mesh, where the final mesh does not include any slivers.

18. The computer-readable storage medium of claim 17, the acts further comprising:
performing numerical simulation based upon the final mesh.

19. The computer-readable storage medium of claim 17, where constructing the point cloud representation of the surface triangulation comprises:
performing adaptive loop subdivision to obtain a representation of the geometry of the surface of the object;
sampling point locations from the representation of the geometry of the surface of the object; and
for each point, storing a normal vector for the point in the computer-readable data storage, where the point cloud representation comprises the point locations and associated normal vectors.

20. The computer-readable storage medium of claim 19, where computing the estimate of the sizing function for the surface of the object comprises:
identifying a violation of a predefined Lipschitz condition between two sizing spheres in the first sizing spheres; and
altering size of a larger of the two sizing spheres upon identifying the violation.
